(19) United States
(12) Patent Application Publication
(10) Pub. No.: US 2012/0099276 A1
(43) Pub. Date: Apr. 26, 2012

(54) WATERPROOF MODULE AND ELECTRICAL EQUIPMENT CABINET EMPLOYING SAME

(75) Inventors: Cheng-Chun Lin, Taoyuan Hsien (TW); Ter-Hsiang Chang, Taoyuan Hsien (TW); Chien-Wei Huang, Taoyuan Hsien (TW)

(73) Assignee: DELTA ELECTRONICS, INC., Taoyuan Hsien (TW)

(21) Appl. No.: 13/252,401

(22) Filed: Oct. 4, 2011

(30) Foreign Application Priority Data
Oct. 20, 2010 (TW) 099135853

(51) Int. Cl. H05K 7/20

(52) U.S. Cl. 361/692

(57) ABSTRACT

An electrical equipment cabinet includes a main body and at least one waterproof module. The main body has a surface with an airflow outlet. The waterproof module is installed on the at least one surface of the main body, and includes a covering member, a first water-retaining structure and a second water-retaining structure. The covering member has a first opening. The first water-retaining structure has a second opening. The second opening is not aligned with the first opening. A periphery of the airflow outlet is enclosed by the second water-retaining structure. A heated airflow generated from an internal portion of the main body is exhausted out of the electrical equipment cabinet through the airflow outlet, the second opening and the first opening. If the electrical equipment cabinet is hit by rain, the rain is sequentially blocked by the covering member, the first water-retaining structure and the second water-retaining structure.

### FIELD OF THE INVENTION

The present invention relates to an electrical equipment cabinet, and more particularly to an outdoor electrical equipment cabinet with a waterproof module.

### BACKGROUND OF THE INVENTION

With increasing development of science and technology, a variety of electronic devices are introduced to the market. Moreover, an electrical equipment cabinet is configured to store precise chips, electronic circuits and electronic devices. In a case that the electrical equipment cabinet is installed in the outdoor environment, the electrical equipment cabinet should be specially designed to withstand stringent conditions such as heat or moisture. During operations of the chips, electronic circuits and electronic devices, a great amount of heat is possibly accumulated within the electrical equipment cabinet. If the heat is not quickly dissipated away, these devices are possibly damaged. For exhausting the heat to the surroundings, a ventilation outlet is usually formed in the outer surface of the main body of the electrical equipment cabinet and in communication with the surroundings.

However, if a strong rain hits the electrical equipment cabinet, the rain or moisture is possibly splashed into the internal portion of the electrical equipment cabinet through the airflow outlet. Under this circumstance, since the electronic devices within the electrical equipment cabinet are moistened or damaged, the use lives of the electronic devices are shortened or the maintenance cost is increased. That is, it is critical to provide an electrical equipment cabinet with a waterproof function.

FIG. 1 is a schematic cross-sectional view illustrating a conventional outdoor electrical equipment cabinet. As shown in FIG. 1, the electrical equipment cabinet 1 includes a main body 10, a covering member 11 and a ventilation space 12. The ventilation space 12 is located between the main body 10 and the covering member 11. The main body 10 has a top plate 13, a first airflow outlet 14, a fan 15 and a plurality of electronic devices 17. The first airflow outlet 14 is formed in the top plate 13. The fan 15 and the electronic devices 17 are disposed within the main body 10. A second airflow outlet 16 is formed in the covering member 11. The location of the second airflow outlet 16 is lower than the location of the first airflow outlet 14. The heated airflow generated from the operating electronic device 17 can be driven by the fan 15 to be exhausted out of the main body 10 through the first airflow outlet 14, the ventilation space 12 and the second airflow outlet 16.

Although the conventional electrical equipment cabinet 1 is effective to dissipate away the heat, there are still some drawbacks. For example, for preventing the rain from entering the internal portion of the electrical equipment cabinet 1 through the second airflow outlet 16 and the first airflow outlet 14, the location of the second airflow outlet 16 should be lower than the location of the first airflow outlet 14. However, in a case that a strong rain hits the electrical equipment cabinet 1, the rain or moisture is possibly splashed into the ventilation space 12 through the second airflow outlet 16 and then introduced into the internal portion of the main body 10 through the first airflow outlet 14. Under this circumstance, the electronic devices 17 are readily damaged due to the damp conditions.

Therefore, there is a need of providing an outdoor electrical equipment cabinet with a waterproof module in order to prevent the moisture from entering the internal portion of the electrical equipment cabinet without largely reducing the heat-dissipating efficacy.

### SUMMARY OF THE INVENTION

The present invention provides an electrical equipment cabinet with a waterproof module for preventing the moisture from entering the internal portion of the electrical equipment cabinet so as to reduce the possibility of damaging the internal electronic devices.

In accordance with an aspect of the present invention, there is provided an electrical equipment cabinet. The electrical equipment cabinet includes a main body and at least one waterproof module. The main body has at least one surface with an airflow outlet. The waterproof module is installed on the at least one surface of the main body, and includes a covering member, a first water-retaining structure and a second water-retaining structure. The covering member has at least one first opening. The first water-retaining structure has at least one second opening. The second opening is not aligned with the first opening. A periphery of the airflow outlet is enclosed by the second water-retaining structure. A heated airflow generated from an internal portion of the main body is exhausted out of the electrical equipment cabinet through the airflow outlet, the at least one second opening and the at least one first opening. If the electrical equipment cabinet is hit by rain, the rain is sequentially blocked by the covering member, the first water-retaining structure and the second water-retaining structure.

In accordance with another aspect of the present invention, there is provided a waterproof module of an electrical equipment cabinet. The electrical equipment cabinet has a main body with at least one surface. An airflow outlet is formed in the surface of the main body. The waterproof module includes a covering member, a first water-retaining structure and a second water-retaining structure. The covering member has at least one first opening. The first water-retaining structure has at least one second opening. The second opening is not aligned with the first opening. A periphery of the airflow outlet is enclosed by the second water-retaining structure. A heated airflow generated from an internal portion of the main body is exhausted out of the electrical equipment cabinet through the airflow outlet, the at least one second opening and the at least one first opening. If the electrical equipment cabinet is hit by rain, the rain is sequentially blocked by the covering member, the first water-retaining structure and the second water-retaining structure.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view illustrating a conventional outdoor electrical equipment cabinet;

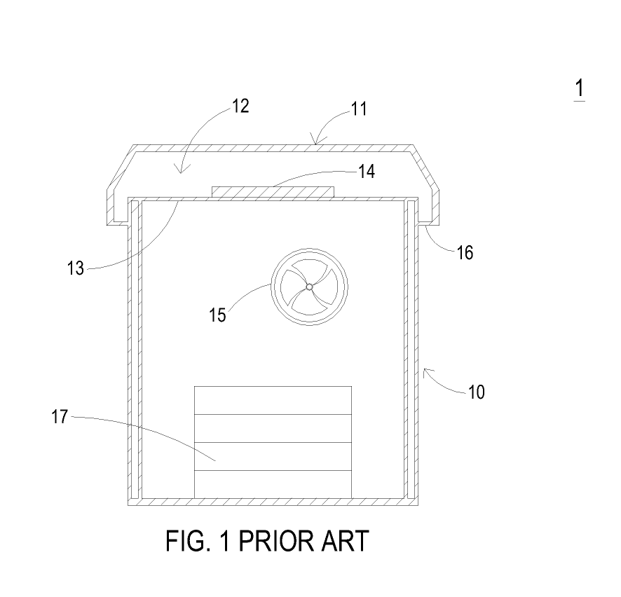

FIG. 2 is a schematic perspective view illustrating an electrical equipment cabinet according to a first embodiment of the present invention;

FIG. 3 is a schematic exploded view illustrating the waterproof module of the electrical equipment cabinet according to the first embodiment of the present invention;

FIG. 4 is a schematic exploded view illustrating the waterproof module of the electrical equipment cabinet according to the first embodiment of the present invention and taken along another viewpoint;

FIG. 5 is a schematic cross-sectional view illustrating an variant of the electrical equipment cabinet according to the first embodiment of the present invention and taken along another viewpoint;

FIG. 6 is a schematic partial perspective view illustrating the electrical equipment cabinet according to a second embodiment of the present invention;

FIG. 7 is a schematic cross-sectional view illustrating the waterproof module of the electrical equipment cabinet as shown in FIG. 6; and

FIG. 8 is a schematic partial perspective view illustrating a waterproof module of an electrical equipment cabinet according to a third embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

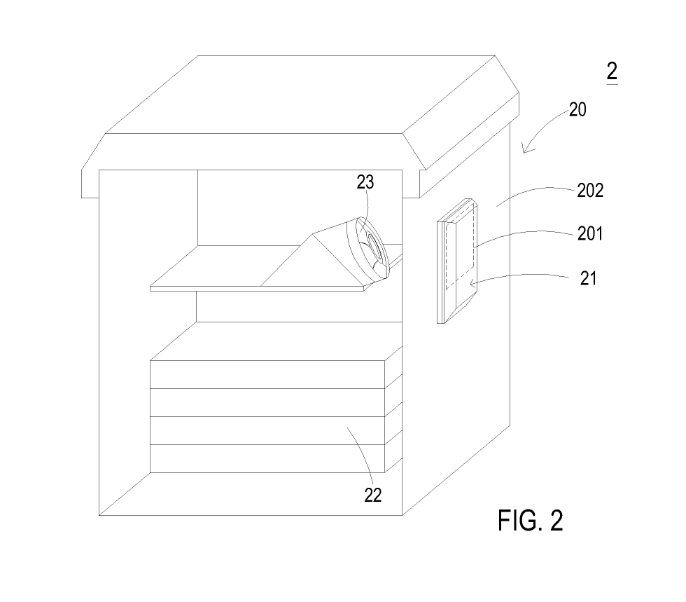

FIG. 2 is a schematic perspective view illustrating an electrical equipment cabinet according to a first embodiment of the present invention. The electrical equipment cabinet 2 is suitably installed in the outdoor environment. As shown in FIG. 2, the electrical equipment cabinet 2 includes a main body 20 and a waterproof module 21. An airflow outlet 201 is located at a surface 202 of the main body 20. The waterproof module 21 is located at the surface 202 of the main body 20 for sheltering the airflow outlet 201. Moreover, an electronic device 22 (e.g. a server or any other heat-generating device or component) and a heat-dissipating device 23 are disposed within the main body 20. The heated airflow generated from the operating electronic device 22 can be driven by the heat-dissipating device 23 to be exhausted out of the main body 20. Consequently, the possibility of thermally damaging the electronic device 22 will be minimized. An example of the heat-dissipating device 23 includes but is not limited to a fan. In some embodiments, the heat-dissipating device 23 is not installed within the main body 22. By natural convection, the heat generated from the operating electronic device 22 can be dissipated outside the main body 20.

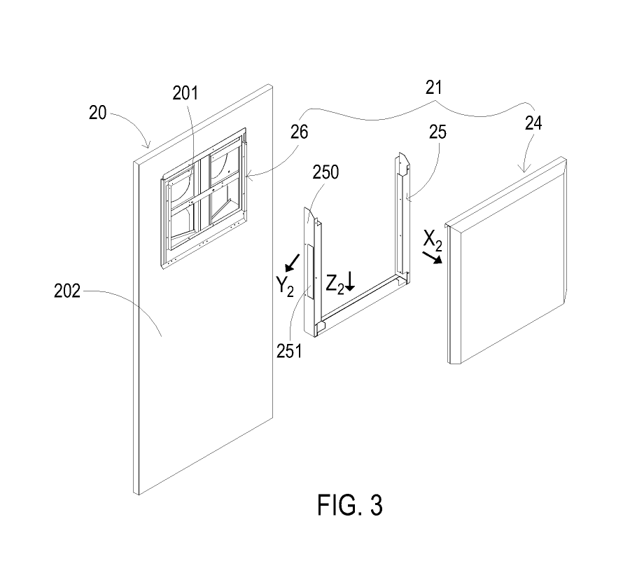

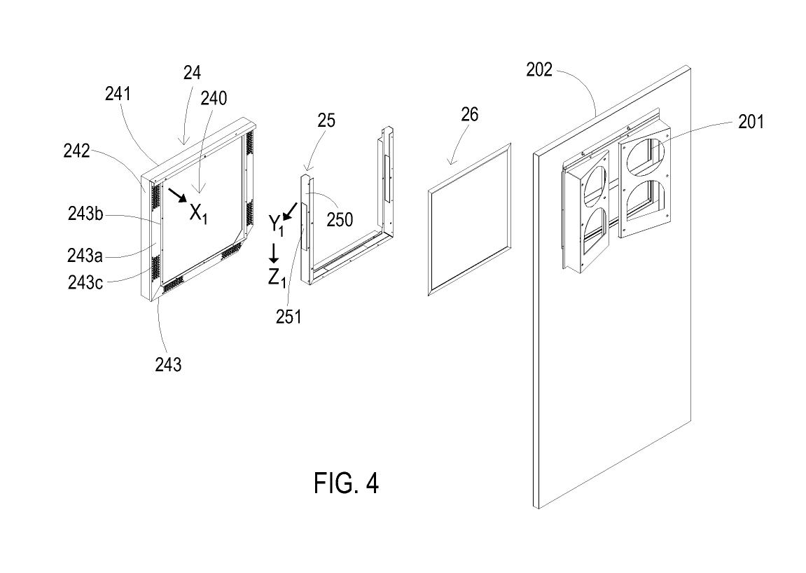

FIG. 3 is a schematic exploded view illustrating the waterproof module of the electrical equipment cabinet according to the first embodiment of the present invention. As shown in FIG. 3, the waterproof module 21 is located at the surface 202 of the main body 20 for sheltering the airflow outlet 201. In this embodiment, the surface 202 is a lateral surface. The waterproof module 21 includes a covering member 24, a first water-retaining structure 25 and a second water-retaining structure 26. The waterproof module 21 is made of a proof material. For reducing the fabricating cost, it is preferred to select the cost-effective proof material. The first water-retaining structure 25 is a water-retaining frame with a plurality of water-retaining bars 250. The water-retaining bar 250 has at least one second opening 251 for allowing the heated airflow to be penetrated therethrough. The second opening 251 is formed in one of the lateral surfaces or the bottom surface of the water-retaining bar 250. In this embodiment, the first water-retaining structure 25 is disposed on the inner wall of the covering member 24. The first water-retaining structure 25 and the covering member 24 are coupled with each other to shelter the airflow outlet 201. Since the covering area of the covering member 24 is relatively larger, the receptacle 240 (as shown in FIG. 4) is relatively broader. That is, the opening ration is increased. After the airflow outlet 201 is sheltered by the covering member 24, smooth convection of the airflow is rendered and the heat-dissipating performance is not adversely affected. In this embodiment, the second water-retaining structure 26 is also a water-retaining frame with a plurality of water-retaining bars. Moreover, the periphery of the airflow outlet 201 is enclosed by the second water-retaining structure 26. For reducing the possibility of introducing the moisture into the airflow outlet 201, it is preferred that the included angle between the second water-retaining structure 26 is smaller than or equal to 90 degrees.

FIG. 4 is a schematic exploded view illustrating the waterproof module of the electrical equipment cabinet according to the first embodiment of the present invention and taken along another viewpoint. As shown in FIG. 4, the airflow outlet 201 is located at a surface 202 of the main body 20. From inside to outside, the second water-retaining structure 26, the first water-retaining structure 25 and the covering member 24 are sequentially shown. In this embodiment, the covering member 24 is a rectangular three-dimensional structure including a first surface 241, a covering frame 242 and a base 243. A receptacle 240 is formed within the covering member 24. The base 243 includes a second surface 243a and an extension part 243b. The second surface 243a is opposed to the first surface 241. The extension part 243b is extended from an edge of the second surface 243a and arranged at the location corresponding to the first water-retaining structure 25. In addition, the extension part 243b is perpendicular to the second surface 243a. At least one first opening 243c is formed in the second surface 243a is a mesh opening, an elongated opening or any other insect-repellent opening structure. For example, an insect-repellent net may be installed at the inner side of the first opening 243c to prevent the insects from entering the first opening 243c.

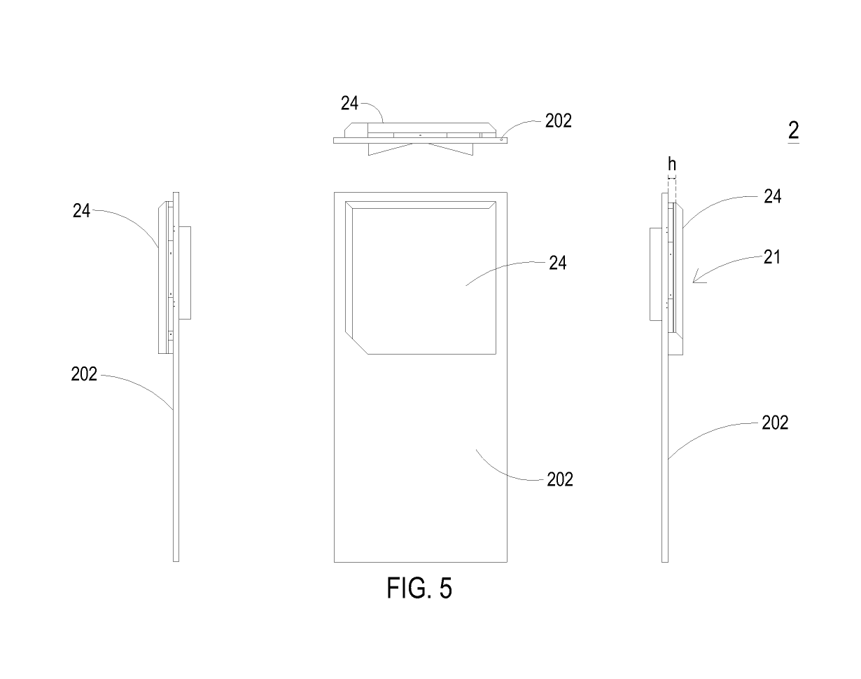

Please refer to FIGS. 2 and 4. The heat generated from the internal portion of the main body 20 will be exhausted to the surroundings along to the following heat-dissipating path. Firstly, the heated airflow is exhausted out of the main body 20 through the airflow outlet 201. Then, the heated airflow is firstly directed to the receptacle 240 of the covering member 24. Then, the heated airflow is directed to a space between the covering frame 242 and the base 243 through the second opening 251 of the first water-retaining structure 25 in the direction Y1. Moreover, the second opening 251 and the first opening 243c are not aligned with each other. That is, the second opening 251 and the first opening 243c face different directions. Consequently, the heated airflow within the receptacle 240 will be directed to the first opening 243c in the direction Z1. After the periphery of the airflow outlet 201 is covered and enclosed by the second water-retaining structure 26, the extension part 243b of the base 243 of the covering member 24 is closely attached on the surface 202 of the main body 20, so that the receptacle 240 is defined between the covering member 24 and the surface 202 of the main body 20. Since the extension part 243b is perpendicular to the second surface 243a of the base 243 and the surface 202 of the main body 20, a gap h is created between the covering member 24 and the surface 202 of the main body 20 (see FIG. 5). Consequently, the heated airflow within the receptacle 240 is directed to the gap h through the first opening 243c of the covering member 24 in the direction X1. Afterwards, the heated airflow is exhausted to the surroundings through the gap h.

From the above discussions, the heated airflow is flowed out of the second opening 251 of the first water-retaining structure 25 in the direction Y1, then flowed to the receptacle 240 of the covering member 24 in the direction Z1, and then flowed out of the first opening 243c of the covering member 24. That is, the heat-dissipating path is a three-dimensional path. Since the opening ratio of the airflow outlet 201 is relatively larger, the heat-dissipating performance of the heat-dissipating device 23 is not adversely affected.

Please refer to FIG. 4 again. For assembling the covering member 24 with the first water-retaining structure 25, the second water-retaining structure 26 and the main body 20, the first water-retaining structure 25 is installed on the inner wall of the covering member 24, and thus a space is defined between the first surface 241, the covering frame 242 and the base 243 of the covering member 24. Moreover, the periphery of the airflow outlet 201 is enclosed by the second water-retaining structure 26. Since there is a gap h between the covering member 24 and the surface 202 of the main body 20, the heated airflow from the internal portion of the electrical equipment cabinet is exhausted out of the covering member 24 through the three-dimensional heat-dissipating path. The heated airflow is directed to the gap h through the first opening 243c of the covering member 24, and then exhausted to the surroundings of the electrical equipment cabinet 2 through the gap h.

Please refer to FIGS. 3, 4 and 5 again. The waterproof module 21 includes the covering member 24, the first water-retaining structure 25 and the second water-retaining structure 26. In a case that a strong rain hits the electrical equipment cabinet 2, the covering member 24 is acted as a first line of defense to block the invasion of the rain. In views of the outward appearance as shown in FIG. 5, almost no opening is seen from the covering member 24 and the electrical equipment cabinet 2. Consequently, if the strong rain hits the electrical equipment cabinet 2, the rain fails to directly flow into the internal portion of the electrical equipment cabinet 2. Since the first opening 243c formed in the second surface 243a of the covering member 24 is in communication with the surroundings, if the rain is splashed into the first opening 243c, the rain may be introduced into the covering member 24 in the direction X2 (see FIG. 3). After the rain is introduced into the covering member 24, due to the gravity force or the adhesion force, the rain may flow along the covering frame 242 of the covering member 24 and the first water-retaining structure 25 in the direction Z2 (see FIG. 3). Since the second opening 251 and the first opening 243c are not aligned with each other, the rain or moisture introduced into the covering member 24 will be blocked in the space between the first surface 241, the covering frame 242 and the base 243 of the covering member 24. Whereas, if some of the rain or moisture is introduced into the receptacle 240 between the main body 20 and the covering member 24 through the second opening 251 of the first water-retaining structure 25 in the direction Y2, the rain or moisture will be completely blocked by the second water-retaining structure 26, which is arranged around the periphery of the airflow outlet 201. That is, the second water-retaining structure 26 is acted as a last line of defense to block the invasion of the rain. Since the invasion of the rain or the moisture can be sequentially blocked by the covering member 24, the first water-retaining structure 25 and the second water-retaining structure 26 of the waterproof module 21, the use of the waterproof module 21 has the waterproof and dustproof efficacy. Moreover, since the airflow can be smoothly transferred through the waterproof module 21, the heat-dissipating performance is not adversely affected.

Please refer to FIG. 5 again. In views of the outward appearance, almost no opening is seen from the covering member 24 and the electrical equipment cabinet 2. Moreover, a plurality of waterproof modules 21 may be installed on different surfaces 202 (e.g. the lateral surfaces and the top surface) of the main body 20 of the electrical equipment cabinet 2. Moreover, the number of waterproof modules 21 may be determined according to the practical requirements. In some embodiments, the waterproof modules 21 are installed on the four lateral surfaces and the top surface of the main body 20 of the electrical equipment cabinet 2 in order to enhance the heat-dissipating efficiency of the heat-dissipating device 23 within the main body 20 of the electrical equipment cabinet 2. Moreover, the locations of the waterproof modules 21 may be varied according to the practical requirements.

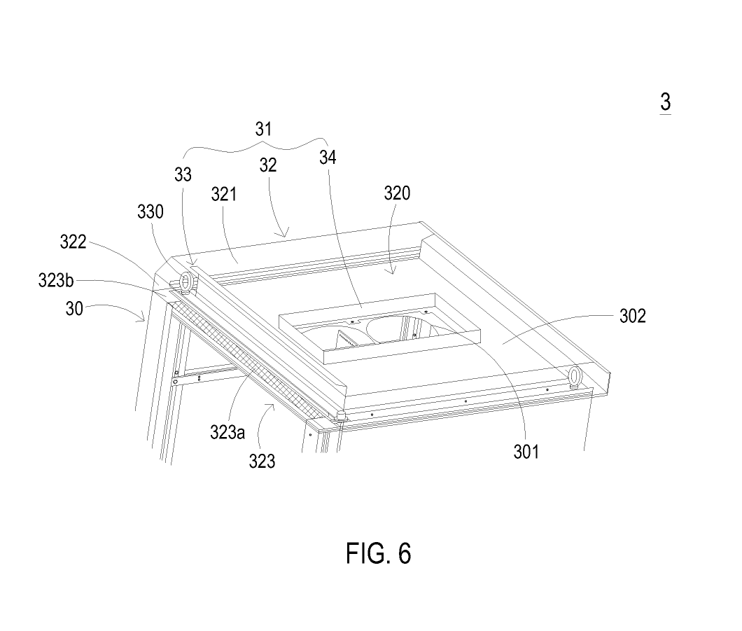

FIG. 6 is a schematic partial perspective view illustrating the electrical equipment cabinet according to a second embodiment of the present invention. The electrical equipment cabinet 3 is suitably installed in the outdoor environment. As shown in FIG. 6, the electrical equipment cabinet 3 includes a main body 30 and a waterproof module 31. An airflow outlet 301 is located at a surface 302 of the main body 30. The waterproof module 31 is located at the surface 302 of the main body 30 for sheltering the airflow outlet 301. In this embodiment, the surface 302 is a top surface of the main body 30. The waterproof module 31 includes a covering member 32, a first water-retaining structure 33 and a second water-retaining structure 34. In this embodiment, the covering member 32 includes a first surface 321, a covering frame 322 and a base 323. A receptacle 320 is formed between the covering member 32 and the main body 30. The way of assembling the covering member 32 is similar to that described in the above embodiments, and is not redundantly described herein. In this embodiment, a first opening 323a is formed in the second surface 323b of the base 323. The first opening 323a is oriented downwardly. The first opening 323a is in communication with the surroundings. The first water-retaining structure 33 is perpendicular to the second surface 323b of the base 323. A second opening 330 is formed in a lateral surface of the first water-retaining structure 33. Moreover, the second opening 330 is not aligned with the first opening 323a.

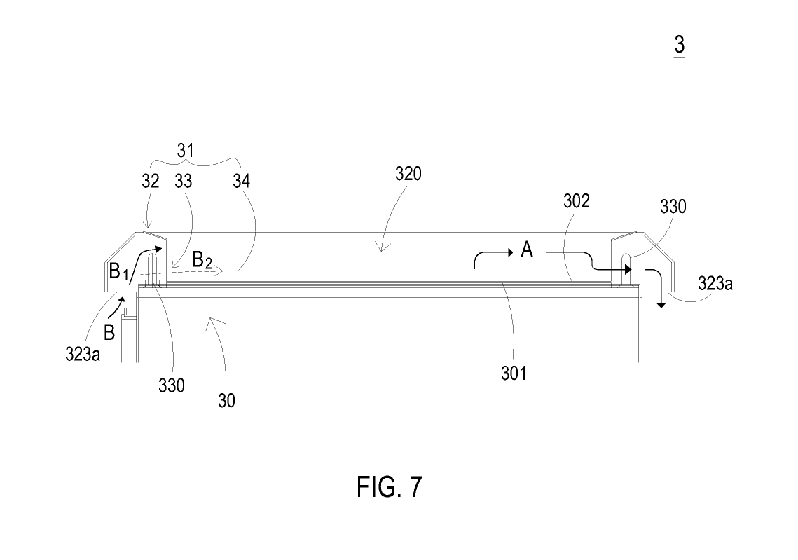

FIG. 7 is a schematic cross-sectional view illustrating the waterproof module of the electrical equipment cabinet as shown in FIG. 6. Please refer to FIGS. 6 and 7. The heated airflow generated from the internal portion of the electrical equipment cabinet 3 is exhausted out of the main body 30 along the heat-dissipating path as indicated by the arrow A. That is, the heated airflow is directed to the receptacle 320 between the main body 30 and the covering member 32 through the airflow outlet 301, and then exhausted out of the electrical equipment cabinet 3 through the second opening 330 of the first water-retaining structure 33 and the first opening 323a of the covering member 32. In such way, the heat generated by the operating electronic device within the main body 30 of the electrical equipment cabinet 3 can be effectively dissipated away to the surroundings. In a case that a storm or a strong rain hits the electrical equipment cabinet 3, the rain or the moisture is possibility introduced into the internal portion of the main body 30 along the path B. Firstly, the covering member 32 is acted as a first line of defense to block the invasion of the rain. If some of the rain or moisture enters the internal portion of the main body 30 through the first opening 323a, the moisture is adsorbed and accumulated on the first water-retaining structure 33 along the path B1. Consequently, a great portion of the moisture can be blocked by the first water-retaining structure 33 and exhausted out of the first opening 323a. If some of the rain or moisture enters the receptacle 320 of the covering member 32, the second water-retaining structure 34 is acted as a last line of defense to block the invasion of the rain or moisture along the path B2. That is, the rain or moisture is further blocked by the second water-retaining structure 34 from being introduced into the airflow outlet 301.

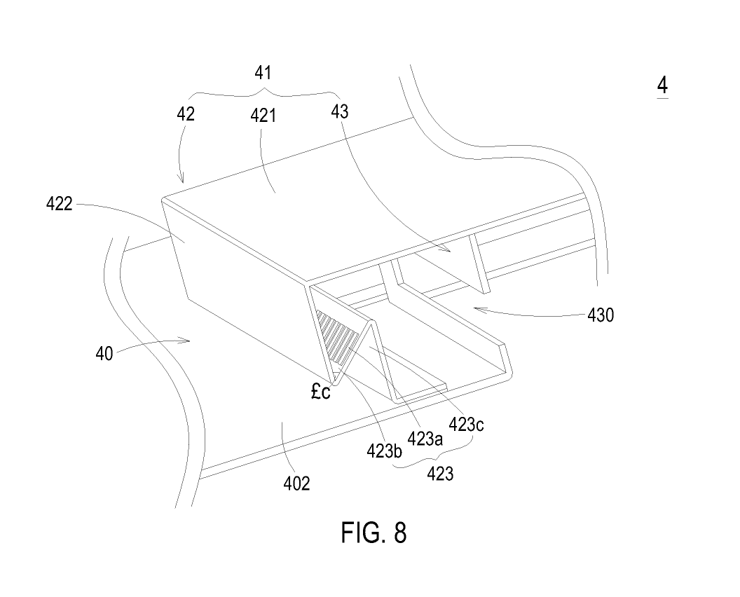

FIG. 8 is a schematic partial perspective view illustrating a waterproof module of an electrical equipment cabinet according to a third embodiment of the present invention. The electrical equipment cabinet 4 is suitably installed in the outdoor environment. As shown in FIG. 8, the electrical equipment cabinet 4 includes a main body 40 and a waterproof module 41. Similarly, the main body 40 has a surface 402, and an airflow outlet (not shown) is located at the surface 402 of the main body 40. The waterproof module 41 is located at the surface 402 of the main body 40 for sheltering the airflow outlet. The waterproof module 41 includes a covering member 42, a first water-retaining structure 43 and a second water-retaining structure (not shown). In this embodiment, the surface 402 is a lateral surface or a top surface according to the practical requirement. The process of assembling the main body 40, the first water-retaining structure 43 and the second water-retaining structure are similar to that of the above embodiments, and is not redundantly described herein.

In this embodiment, the covering member 42 is a rectangular three-dimensional structure including a first surface 421, a covering frame 422 and a base 423. The base 243 includes a second surface 423b and an extension part 423c. An included angle θ is defined between the second surface 423b and the extension part 423c, wherein the included angle θ is greater than 0 degree and smaller than 90 degrees. Moreover, at least one first opening 423a is formed in the second surface 423b. The first opening 423a is a mesh opening, an elongated opening or any other insect-repellent opening structure. The extension part 423c is extended from an edge of the second surface 423b and opposed to the first water-retaining structure 43. In addition, the extension part 423c is in contact with the surface 402 of the main body 40 of the electrical equipment cabinet 4.

The first water-retaining structure 43 is a water-retaining frame with at least one second opening 430 for allowing the heated airflow to be penetrated therethrough. Since the first water-retaining structure 43 and the second surface 423b of the covering member 42 face different directions, the second opening 430 and the first opening 423a are not aligned with each other.

Please refer to FIG. 8 again. In a case that a strong rain hits the electrical equipment cabinet 4, the covering member 42 is acted as a first line of defense to block the invasion of the rain. In views of the outward appearance as shown in FIG. 8, almost no opening is seen from the covering member 42 and the electrical equipment cabinet 4. Since the first opening 423a formed in the second surface 423b of the covering member 42 is in communication with the surroundings, if the rain is splashed into the first opening 423a, the rain may be directed to a connecting zone between the second surface 423b and the extension part 423c (i.e. the zone having the included angle θ). Due to the included angle θ between the second surface 423b and the extension part 423c, the rain may be exhausted to the surrounding because of gravity force or accumulated at the connecting zone.

Moreover, even if some of the rain or moisture is blown into the internal portion of the covering member 42, the rain or moisture will be blocked by the first water-retaining structure 43 because the first water-retaining structure 43 is opposed to the covering frame 422. Due to the gravity force, the rain or moisture may be aggregated or collected between the first water-retaining structure 43 and the extension part 423c. In other words, the first water-retaining structure 43 is acted as a second line of defense to block the invasion of the rain or moisture.

Moreover, even if some of the rain or moisture is introduced into the space between the main body 40 and the covering member 42 through the second opening 430, the rain or moisture will be completely blocked by the second water-retaining structure (not shown), which is arranged around the periphery of the airflow outlet. That is, the second water-retaining structure is acted as a last line of defense to block the invasion of the rain.

The covering member 42, the first water-retaining structure 43 and the second water-retaining structure of the waterproof module 41 are collectively defined as three lines of defense to block the external rain, moisture or dusk from entering the electrical equipment cabinet 4. In other words, the waterproof module 41 is able to achieve the waterproof, dustproof and heat-dissipating functions.

In the above embodiments, the waterproof module of the present invention is installed on the lateral surface or the top surface of the main body of the electrical equipment cabinet. The location and number of the waterproof module may be varied according to the practical requirements. Regardless of whether the waterproof module is installed on the lateral surface or the top surface of the main body, the airflow path and the water path can be separated from each other by the covering member, the first water-retaining structure and the second water-retaining structure of the waterproof module. By the waterproof module, the heat can be dissipated away to the surroundings along the airflow path, and the water path can be blocked. That is, since the external rain or moisture splashed into the internal portion of the covering member is blocked by the first water-retaining structure and the second water-retaining structure, the rain or moisture fails to be introduced into the internal portion of the main body. Consequently, the use life of the electronic device within the main body will be prolonged. Moreover, the first water-retaining structure and the second water-retaining structure have simplified configurations and easily fabricated. By means of several water-retaining bars, the external rain or moisture can be effectively blocked. Moreover, since the first water-retaining structure and the second water-retaining structure are made of cost-effective and waterproof material and a part of the waterproof module may be integrated with the covering member or the airflow outlet, the waterproof module is cost-effective or easily fabricated.

From the above description, the waterproof module is suitably used in the outdoor environment. Since the first opening and the second opening are not aligned with each other and the covering member, the first water-retaining structure and the second water-retaining structure are arranged in a staggered form, the waterproof, dustproof and heat-dissipating functions are achieved. Moreover, the waterproof module is simple, easily fabricated and cost-effective.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An electrical equipment cabinet, comprising:
a main body having at least one surface with an airflow outlet; and
at least one waterproof module installed on said at least one surface of said main body, and comprising:
a covering member having at least one first opening;
a first water-retaining structure having at least one second opening, wherein said second opening is not aligned with said first opening; and
a second water-retaining structure configured to enclose a periphery of said airflow outlet;
wherein a heated airflow generated from an internal portion of said main body is exhausted out of said electrical equipment cabinet through said airflow outlet, said at least one second opening and said at least one first opening, wherein if said electrical equipment cabinet is hit by rain, said rain is sequentially blocked by said covering member, said first water-retaining structure and said second water-retaining structure.

2. The electrical equipment cabinet according to claim 1, wherein said at least one surface is a lateral surface or a top surface of said main body.

3. The electrical equipment cabinet according to claim 1, wherein said covering member is a rectangular three-dimensional structure comprising a first surface, a covering frame and a base.

4. The electrical equipment cabinet according to claim 3, wherein said first water-retaining structure is perpendicular to said base.

5. The electrical equipment cabinet according to claim 3, wherein said base of said covering member has a second surface, and said at least one first opening is located at said second surface of said base.

6. The electrical equipment cabinet according to claim 5, wherein corresponding to said first water-retaining structure, said base further comprises an extension part, which is extended from an edge of said second surface of said base.

7. The electrical equipment cabinet according to claim 1, wherein said first water-retaining structure is a water-retaining frame with a plurality of water-retaining bars, wherein said at least one second opening is located at said water-retaining bar, and said at least one second opening is not aligned with said sat least one first opening.

8. The electrical equipment cabinet according to claim 1, wherein said second water-retaining structure is a water-retaining frame with a plurality of water-retaining bars, and said periphery of the airflow outlet is enclosed by said water-retaining bars.

9. The electrical equipment cabinet according to claim 1, wherein an included angle between said second water-retaining structure and said surface of said main body is smaller than or equal to 90 degrees.

10. A waterproof module of an electrical equipment cabinet, said electrical equipment cabinet having a main body with at least one surface, an airflow outlet being formed in said surface of said main body, said waterproof module comprising:
a covering member having at least one first opening;
a first water-retaining structure having at least one second opening, wherein said second opening is not aligned with said first opening; and
a second water-retaining structure configured to enclose a periphery of said airflow outlet,
wherein a heated airflow generated from an internal portion of said main body is exhausted out of said electrical equipment cabinet through said airflow outlet, said at least one second opening and said at least one first opening, wherein if said electrical equipment cabinet is hit by rain, said rain is sequentially blocked by said covering member, said first water-retaining structure and said second water-retaining structure.
